(19) United States
(12) Patent Application Publication
(10) Pub. No.: US 2026/0115859 A1
(43) Pub. Date: Apr. 30, 2026

(54) POLISHING HEAD, POLISHING DEVICE PROVIDED WITH SAME, AND SUBSTRATE PROCESSING DEVICE

(71) Applicant: SCREEN Holdings Co., Ltd., Kyoto (JP)

(72) Inventors: Hiroaki ISHII, Kyoto (JP); Junichi ISHII, Kyoto (JP)

(21) Appl. No.: 18/693,391

(22) PCT Filed: Apr. 25, 2022
(86) PCT No.: PCT/JP2022/018683

§ 371 Date: Jul. 11, 2025

(30) Foreign Application Priority Data
Sep. 24, 2021 (JP) 2021-155330

(51) Int. Cl. B24B 37/34; B24B 37/005

(52) U.S. Cl. CPC B24B 37/34; B24B 37/005

(57) ABSTRACT

Dust particles generated on a back surface of a substrate as a result of polishing by a polishing tool are also forced out toward an outer periphery of the polishing tool by centrifugal force. Then, nitrogen gas is ejected from an ejection port. This forces the dust particles adhering to the back surface of the substrate to separate from the back surface of the substrate. The dust particles are sucked through a suction port. This makes the dust particles less likely to remain on the back surface of the substrate, so that it is possible to increase the rate of removal of the dust particles generated as a result of polishing.

### TECHNICAL FIELD

The present invention relates to a polishing head that polishes a back surface of a substrate and a polishing device provided with the polishing head, and a substrate processing device. Examples of the substrate include a semiconductor substrate, a substrate for a flat panel display (FPD), a glass substrate for a photomask, a substrate for an optical disc, a substrate for a magnetic disk, a ceramic substrate, a substrate for a solar cell, and the like. Examples of the FPD include a liquid crystal display device, an organic electroluminescence (EL) display device, and the like. Herein, the back surface of the substrate refers to a surface where no electronic circuit is formed as opposed to a surface of the substrate where an electronic circuit is formed.

### BACKGROUND ART

Examples of the polishing device that polishes the back surface of the substrate include a polishing device including a polishing tool, a head body, a recess, and a polishing head provided with a suction hole (see, for example, Patent Literature 1).

The polishing tool includes a synthetic grindstone. The synthetic grindstone is formed of an abrasive (abrasive grains) bound with a resin binder. The synthetic grindstone is molded in an annular shape. The head body holds the polishing tool. The recess having an opening formed to face the back surface of the substrate. The suction hole is formed in the head body, communicates with the recess, and is connected to a suction pump. Polishing using this polishing head corresponds to dry chemo-mechanical grinding, and is also called chemo-mechanical grinding (CMG).

In the polishing device using the polishing head configured as described above, a central portion of the polishing tool is sucked through the suction hole of the polishing head. Therefore, dust particles generated as a result of polishing by the polishing tool are sucked by the suction pump through the suction hole. As a result, processing can be performed so as to reduce dust particles remaining on the substrate surface.

### CITATION LIST

### Patent Literature

Patent Literature 1: JP 2020-4948 A

### SUMMARY OF INVENTION

### Technical Problem

A known technique having such a configuration, however, has the following problem.

That is, there has been a problem of defocus (also known as out-of-focus) of an extreme ultraviolet (EUV) lithography machine due to a degree of substrate flatness of a back surface of a substrate (for example, a wafer). The possible causes of poor flatness include a particle, a scratch, a film residue, and the like. It has therefore been studied to remove such causative factors with the polishing head.

With the known polishing head, however, only the central portion is sucked. Therefore, some of dust particles generated near the outer periphery of the polishing tool may remain adhering to the substrate surface without being removed by suction. As a result, the defocus problem is not eliminated, and processing after polishing may be adversely affected. In other words, there is a problem that the rate of removal of dust particles generated as a result of polishing from the substrate surface is low.

The present invention has been made in view of such circumstances, and it is therefore an object of the present invention to provide a polishing head that allows an increase in rate of removal of dust particles generated as a result of polishing, a polishing device provided with the polishing head, and a substrate processing device.

### Solution to Problem

In order to achieve the object, the present invention is configured as follows.

That is, in the invention according to claim 1, a polishing head that polishes a substrate includes a polishing tool including a resin body in which abrasive grains are dispersed, an ejection port through which gas is ejected toward dust particles generated as a result of polishing by the polishing tool, and a suction port through which the dust particles generated as a result of polishing by the polishing tool are sucked.

[Operation and effect] In the invention according to claim 1, the gas is ejected from the ejection port toward the dust particles generated as a result of polishing by the polishing tool. This forces the dust particles adhering to the substrate surface to separate from the substrate surface. The dust particles are sucked through the suction port. This makes the dust particles less likely to remain on the substrate surface, so that it is possible to increase the rate of removal of the dust particles generated as a result of polishing.

In the invention according to claim 2, it is preferable that the ejection port be provided along an outer peripheral surface of the polishing tool, and the suction port be provided along the outer peripheral surface of the polishing tool and be provided in a line-symmetrical relation with the ejection port as viewed from above.

The outer peripheral surface of the polishing tool is divided in line symmetry as viewed from above, and the resultant surfaces are used as the ejection port and the suction port. This makes it possible to keep a balance between supply and suction of the gas on the outer peripheral surface of the polishing tool satisfactory. It is therefore possible to remove the dust particles satisfactorily.

In the present invention, it is further preferable that the polishing tool be provided in an annular shape as viewed from above, the ejection port be provided at a center of the polishing tool, and the suction port be provided all over an outer peripheral surface of the polishing tool (claim 3).

The gas ejected from the center flows toward the outer periphery of the polishing tool along the substrate surface. It is therefore possible to efficiently suck the gas containing the dust particles through the suction port.

In the present invention, it is further preferable that the polishing tool include a porous member having holes communicating with each other, the ejection port be provided on a lower surface of the polishing tool, and
the suction port be provided all over an outer periphery of the polishing tool (claim 4).

The gas can be supplied to the polishing tool of the porous member and be ejected toward the dust particles from almost the entire lower surface of the polishing tool. It is therefore possible to efficiently force the dust particles out toward the outer periphery.

In the present invention, it is further preferable that the gas be discontinuously ejected from the ejection port (claim 5).

When the gas is continuously ejected, the dust particles may be pressed against the substrate surface and thus cannot be removed. Therefore, when the gas is discontinuously and intermittently ejected, the dust particles can be easily removed.

Further, in the invention according to claim 6, a polishing device that polishes a substrate includes a polishing head according to any one of claims 1 to 5, a head drive mechanism that drives the polishing head to rotate about a vertical axis, a holding and rotating unit that rotates the substrate held in a horizontal position, a gas supply pipe through which gas is supplied to an ejection port of the polishing head, and a suction pipe through which suction is performed from a suction port of the polishing head.

[Operation and effect] In the invention according to claim 6, the head drive mechanism causes the polishing head to rotate about the vertical axis. The substrate is rotated in a horizontal position by the holding and rotating unit. In this state, the polishing tool of the polishing head is brought into contact with the substrate surface to perform polishing. At this time, the gas is supplied to the polishing head through the gas supply pipe, thereby forcing the dust particles adhering to the substrate surface to separate from the substrate surface. Furthermore, the dust particles are sucked together with the gas from the suction port through the suction pipe. This makes the dust particles less likely to remain on the substrate surface, so that it is possible to increase the rate of removal of the dust particles generated as a result of polishing.

In the present invention, it is further preferable that the polishing device further include a control valve that controls a flow of the gas through the gas supply pipe, and a control unit that operates the control valve, and the control unit operate the control valve to intermittently eject the gas from the polishing head (claim 7).

When the gas is continuously ejected, the dust particles may be pressed against the substrate surface and thus cannot be removed. Therefore, the control unit operates the control valve to discontinuously eject the gas from the polishing head. When the gas is discontinuously and intermittently ejected, the dust particles can be easily removed.

In the present invention, it is further preferable that the control unit operate the control valve such that a flow rate of the gas ejected from the ejection port does not exceed a flow rate of the gas sucked through the suction pipe (claim 8).

Such flow rate control makes it possible to prevent a situation where the gas ejected from the ejection port prevents the dust particles from being sucked from the suction port and causes the dust particles to scatter around.

Further, a substrate processing device according to claim 9 includes a polishing device according to any one of claims 1 to 6.

[Operation and effect] In the invention according to claim 9, when the substrate is polished by the polishing device, the head drive mechanism causes the polishing head to rotate about the vertical axis. The substrate is rotated in a horizontal position by the holding and rotating unit. In this state, the polishing tool of the polishing head is brought into contact with the substrate surface to perform polishing. At this time, the gas is supplied to the polishing head through the gas supply pipe, thereby forcing the dust particles adhering to the substrate surface to separate from the substrate surface. Furthermore, the dust particles are sucked together with the gas from the suction port through the suction pipe. This makes the dust particles less likely to remain on the substrate surface, so that it is possible to increase the rate of removal of the dust particles generated as a result of polishing. As a result, the substrate can be processed cleanly.

### Advantageous Effects of Invention

The polishing head according to the present invention ejects the gas from the ejection port toward the dust particles generated as a result of polishing by the polishing tool. This forces the dust particles adhering to the substrate surface to separate from the substrate surface. The dust particles are sucked through the suction port. This makes the dust particles less likely to remain on the substrate surface, so that it is possible to increase the rate of removal of the dust particles generated as a result of polishing.

### BRIEF DESCRIPTION OF DRAWINGS

FIG. 1 is a plan view illustrating a configuration of a substrate processing device according to a first embodiment.

FIGS. 2A to 2D are diagrams for describing a reversing unit.

FIG. 3 is a side view illustrating a configuration of a polishing unit.

FIG. 4A is a plan view illustrating a configuration of a holding and rotating unit, and FIG. 4B is a partially enlarged longitudinal cross-sectional view illustrating the configuration of the holding and rotating unit.

FIG. 5 is a diagram illustrating a configuration of a polishing mechanism of the polishing unit.

FIG. 6 is a diagram illustrating a configuration of an inspecting unit.

FIG. 7 is a flowchart illustrating how the substrate processing device according to the first embodiment operates.

FIG. 8A is a longitudinal cross-sectional view schematically illustrating a substrate before being subjected to an etching process, FIG. 8B is a longitudinal cross-sectional view schematically illustrating the substrate after being subjected to the etching process (before being subjected to a back surface polishing process), and FIG. 8C is a longitudinal cross-sectional view schematically illustrating the substrate after the back surface polishing process.

FIG. 9 is a flowchart illustrating details of a wet etching process.

FIG. 10 is a diagram showing a relation between a temperature to which the substrate is heated and a polishing rate.

FIG. 11 is a flowchart illustrating details of a substrate cleaning process.

FIG. 12 is a diagram illustrating a preferred configuration of the polishing mechanism of the polishing unit.

FIG. 13 is a longitudinal cross-sectional view of a polishing head according to the first embodiment.

FIG. 14 is a bottom view of the polishing head according to the first embodiment.

FIG. 15 is a longitudinal cross-sectional view of a polishing head according to a second embodiment.

FIG. 16 is a bottom view of the polishing head according to the second embodiment.

FIG. 17 is a longitudinal cross-sectional view of a polishing head according to a third embodiment.

FIG. 18 is a bottom view of the polishing head according to the third embodiment.

### DESCRIPTION OF EMBODIMENTS

The present invention will be described below with reference to embodiments.

### First Embodiment

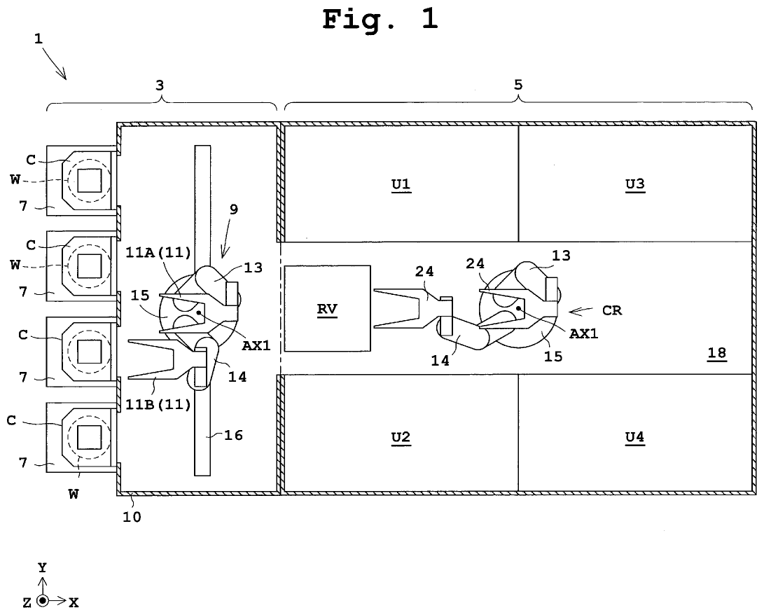

Hereinafter, a first embodiment of the present invention will be described with reference to the drawings. FIG. 1 is a plan view illustrating a configuration of a substrate processing device according to the first embodiment.

### (1) Configuration of Substrate Processing Device

Refer to FIG. 1. A substrate processing device 1 includes an indexer block 3 and a processing block 5. Note that each block is also referred to as a region.

The indexer block 3 includes a plurality of (for example, four) carrier loading tables 7 and an indexer robot 9. The four carrier loading tables 7 are arranged on an outer surface of a housing 10. On each of the four carrier loading tables 7, a carrier C is loaded. The carrier C accommodates a plurality of substrates W. Each substrate W in the carrier C is in a horizontal position with its device surface oriented upward (facing upward). As the carrier C, for example, a front open unified pod (FOUP), a standard mechanical inter face (SMIF) pod, or an open cassette is used. The substrate W is a silicon substrate, and is formed in, for example, a disk shape.

The indexer robot 9 takes the substrate W from the carrier C loaded onto each carrier loading table 7, or stores the substrate W into the carrier C. The indexer robot 9 is disposed inside the housing 10. The indexer robot 9 includes two hands 11 (11A, 11B), two articulated arms 13 and 14, a lift stage 15, and a guide rail 16. Each of the two hands 11 holds the substrate W. The first hand 11A is connected to a distal end of the articulated arm 13. The second hand 11B is connected to a distal end of the articulated arm 14.

Each of the two articulated arms 13 and 14 is of, for example, a SCARA type. The two articulated arms 13 and 14 have their respective proximal ends attached to the lift stage 15. The lift stage 15 is extendable in the vertical direction. This allows the two hands 11 and the two articulated arms 13 and 14 to move up and down. The lift stage 15 is rotatable about a center axis AX1 extending in the vertical direction. This allows the two hands 11 and the two articulated arms 13 and 14 to change their respective orientations. The lift stage 15 of the indexer robot 9 is movable along the guide rail 16 extending in a Y direction.

The indexer robot 9 includes a plurality of electric motors. The indexer robot 9 is driven by the plurality of electric motors. The indexer robot 9 conveys the substrate W between the carrier C loaded onto each of the four carrier loading tables 7 and a reversing unit RV to be described later.

The processing block 5 includes a conveyance space 18, a substrate conveying robot CR, the reversing unit RV, and a plurality of (for example, eight) processing units (processing chambers) U1 to U4. In FIG. 1, each of the processing units U1 to U4 includes, for example, two layers in the vertical direction. The processing unit U1 is an inspecting unit 20. The processing units U2, U3, and U4 are polishing units 22. The number and type of the processing units can be changed as appropriate.

The substrate conveying robot CR and the reversing unit RV are arranged in the conveyance space 18. The reversing unit RV is disposed between the indexer robot 9 and the substrate conveying robot CR. The processing units U1 and U3 are arranged side by side in an X direction along the conveyance space 18. Further, the processing units U2 and U4 are arranged side by side in the X direction along the conveyance space 18. The conveyance space 18 is disposed between the processing units U1 and U3 and the processing units U2 and U4.

The substrate conveying robot CR is almost identical in configuration to the indexer robot 9. That is, the substrate conveying robot CR has two hands 24. Note that the other components of the substrate conveying robot CR are denoted by the same reference numerals as assigned to the corresponding components of the indexer robot 9. Unlike the lift stage 15 of the indexer robot 9, a lift stage 15 of the substrate conveying robot CR is fixed to a floor surface. Alternatively, the lift stage 15 of the substrate conveying robot CR may include a guide rail extending in the X direction so as to be movable in the X direction. The substrate conveying robot CR conveys the substrate W between the reversing unit RV and the eight processing units U1 to U4.

### (1-1) Reversing Unit RV

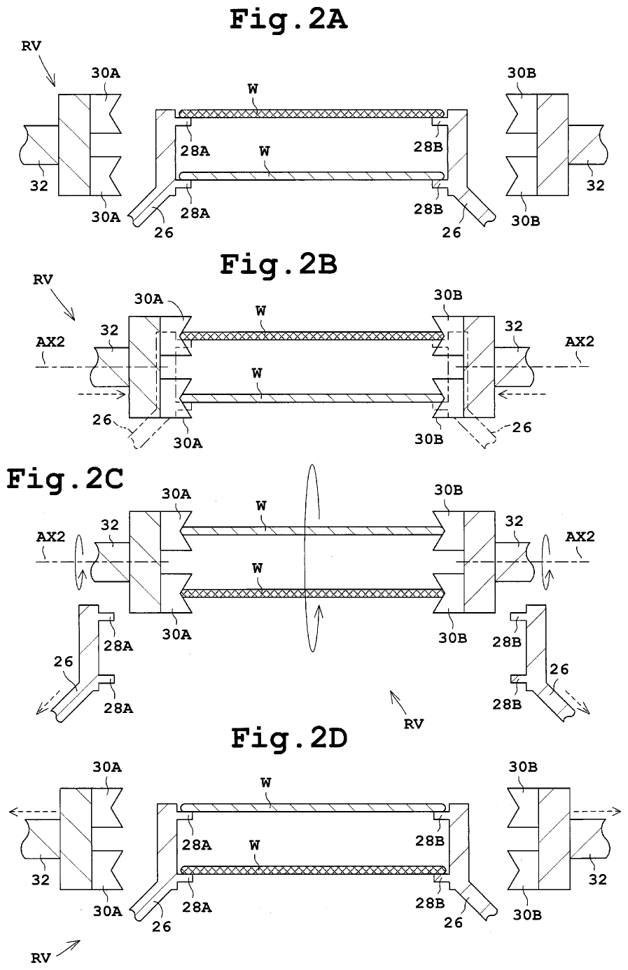

FIGS. 2A to 2D are diagrams for describing the reversing unit RV. The reversing unit RV includes a support member 26, loading members 28A and 28B, clamping members 30A and 30B, a slide shaft 32, and a plurality of electric motors (not illustrated). The left and right support members 26 are provided with the loading members 28A and 28B, respectively. Further, the left and right slide shafts 32 are provided with the clamping members 30A and 30B, respectively. The plurality of electric motors drives the support members 26 and the slide shafts 32. Note that the loading members 28A and 28B and the clamping members 30A and 30B are provided at positions where the loading members 28A and 28B and the clamping members 30A and 30B do not come into contact with each other.

Refer to FIG. 2A. For example, the substrate W conveyed by the indexer robot 9 is loaded onto each of the loading members 28A and 28B. Refer to FIG. 2B. The left and right slide shafts 32 come closer to each other along a horizontal axis AX2. This causes the clamping members 30A and 30B to clamp two substrates W. Refer to FIG. 2C. Thereafter, the left and right loading members 28A and 28B move downward while separating away from each other. Thereafter, the clamping members 30A and 30B rotate by 180° about the horizontal axis AX2. As a result, each substrate W is reversed.

Refer to FIG. 2D. Thereafter, the left and right loading members 28A and 28B move up while coming closer to each other. Thereafter, the left and right slide shafts 32 separate away from each other along the horizontal axis AX2. As a result, the two substrates W clamped by the clamping members 30A and 30B are released and then loaded onto the loading members 28A and 28B. In FIGS. 2A to 2D, the reversing unit RV is capable of reversing two substrates W, but the reversing unit RV may be configured to reverse three or more substrates W.

### (1-2) Polishing Unit 22

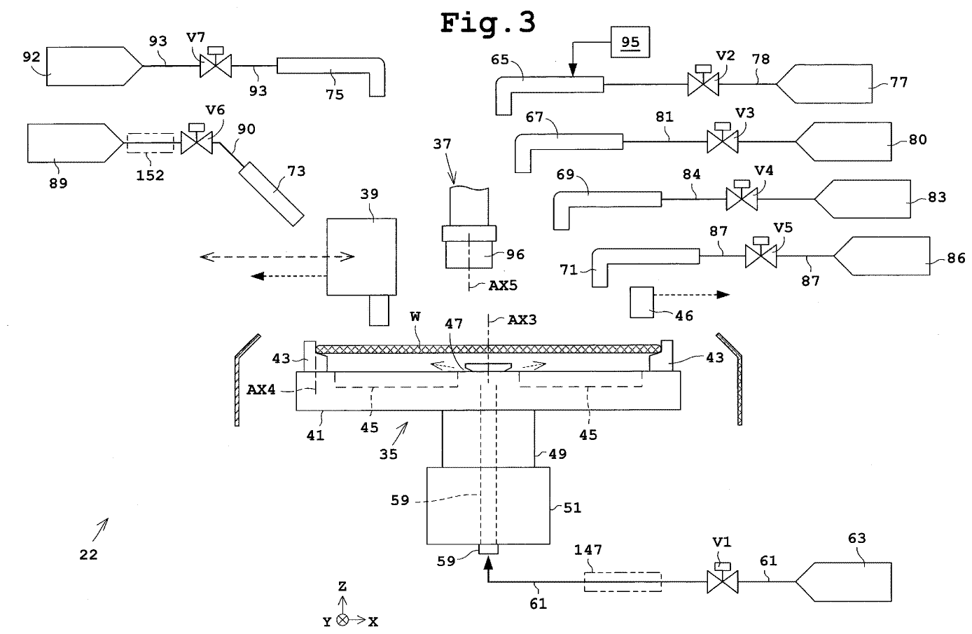

FIG. 3 is a diagram illustrating the polishing unit 22. The polishing unit 22 includes a holding and rotating unit 35, a polishing mechanism 37, and a substrate thickness measuring device 39.

The holding and rotating unit 35 holds one substrate W in a horizontal position with a back surface of the substrate W facing upward, and rotates the held substrate W. Here, the back surface of the substrate W refers to a surface of the substrate W where no electronic circuit is formed as opposed to a side (device surface) where an electronic circuit is formed. The device surface of the substrate W held by the holding and rotating unit 35 faces downward.

The holding and rotating unit 35 includes a spin base 41, six holding pins 43, a hot plate 45, and a gas discharge port 47. The spin base 41 is formed in a disk shape and is disposed in a horizontal position. A rotation axis AX3 extending in the vertical direction passes through the center of the spin base 41. The spin base 41 is rotatable about the rotation axis AX3.

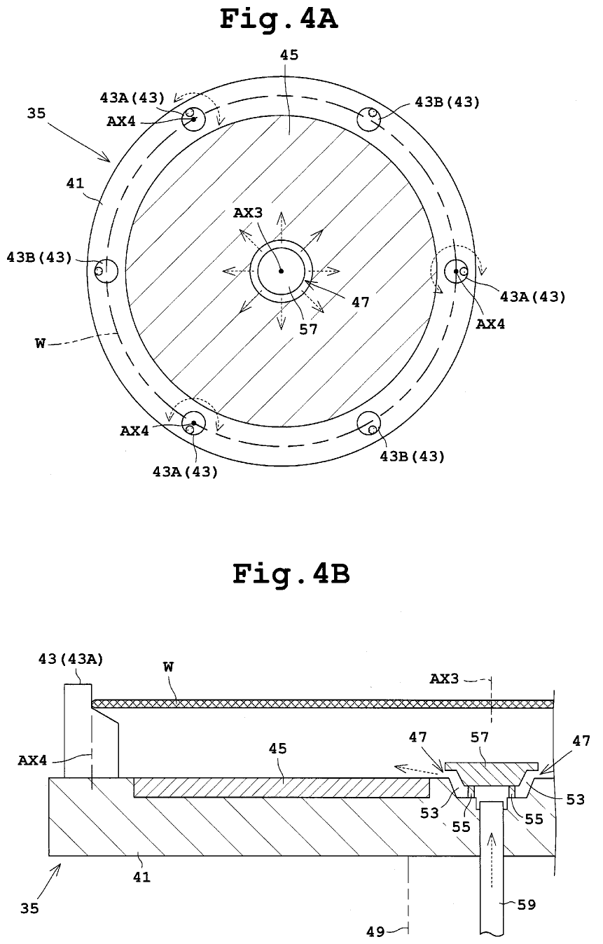

FIG. 4A is a plan view of the spin base 41 and the six holding pins 43 of the holding and rotating unit 35. The six holding pins 43 are provided on an upper surface of the spin base 41. The six holding pins 43 are provided in a ring shape around the rotation axis AX3. Further, the six holding pins 43 are provided at equal intervals on an outer edge side of the spin base 41. The six holding pins 43 holds the substrate W with the substrate W apart from the spin base 41 and the hot plate 45 to be described later. Furthermore, the six holding pins 43 are configured to clamp a side surface of the substrate W. That is, the six holding pins 43 can hold the substrate W with the substrate W apart from the upper surface of the spin base 41.

The six holding pins 43 are divided into three holding pins 43A that rotate and three holding pins 43B that do not rotate. The three holding pins 43A are rotatable about a rotation axis AX4 extending in the vertical direction. As each holding pin 43A rotates about the rotation axis AX4, the three holding pins 43A hold the substrate W and release the held substrate W. For example, magnetic attraction force or repulsive force produced by a magnet causes each holding pin 43A to rotate about the rotation axis AX4. The number of the holding pins 43 is not limited to six, and only needs to be at least three. The substrate W may be held by at least three holding pins 43 including the holding pin 43A that rotates and the holding pin 43B that does not rotate.

The hot plate 45 is provided on the upper surface of the spin base 41. The hot plate 45 has, for example, an electric heater with a nichrome wire provided therein. The hot plate 45 is formed in a donut shape and a disk shape. The hot plate 45 heats the substrate W with radiant heat. The hot plate 45 further heats gas discharged from the gas discharge port 47 to be described later, so that the substrate W is heated by the gas. The temperature of the substrate W is measured by a temperature sensor 46 of a noncontact type. The temperature sensor 46 includes a detection element that detects infrared rays emitted from the substrate W.

A shaft 49 is provided on a lower surface of the spin base 41. A rotating mechanism 51 includes an electric motor. The rotating mechanism 51 rotates the shaft 49 about the rotation axis AX3. That is, the rotating mechanism 51 rotates the substrate W held by the six holding pins 43 (specifically, the three holding pins 43A) provided on the spin base 41 about the rotation axis AX3.

Refer to FIGS. 3 and 4B. The gas discharge port 47 is opened on the upper surface of the spin base 41 and is provided at the center of the spin base 41. A flow path 53 is opened upward and is provided at the center of the spin base 41. Further, the flow path 53 has a discharge member 57 provided with a plurality of spacers 55 interposed between the discharge member 57 and the flow path 53. The gas discharge port 47 is a ring-shaped opening formed by a gap between the discharge member 57 and the flow path 53.

A gas supply pipe 59 is provided extending through the shaft 49 and the rotating mechanism 51 along the rotation axis AX3. Gas (for example, an inert gas such as nitrogen) is fed from a gas supply source 63 to the gas supply pipe 59 through a gas pipe 61. The gas pipe 61 is provided with an on-off valve V1. The on-off valve V1 allows or stops the supply of gas. When the on-off valve V1 is open, the gas is discharged from the gas discharge port 47. When the on-off valve V1 is closed, the gas is not discharged from the gas discharge port 47. The gas discharge port 47 allows the gas to flow from the center side of the substrate W toward the outer edge of the substrate W through a gap between the substrate W and the spin base 41.

Next, a configuration for supplying a chemical solution, a rinse solution, and gas will be described. The polishing unit 22 includes a first chemical solution nozzle 65, a second chemical solution nozzle 67, a first cleaning solution nozzle 69, a second cleaning solution nozzle 71, a rinse solution nozzle 73, and a gas nozzle 75.

A chemical solution pipe 78 through which a first chemical solution is fed from a first chemical solution supply source 77 is connected to the first chemical solution nozzle 65. The first chemical solution is, for example, hydrofluoric acid (HF). The chemical solution pipe 78 is provided with an on-off valve V2. The on-off valve V2 allows or stops the supply of the first chemical solution. When the on-off valve V2 is open, the first chemical solution is supplied from the first chemical solution nozzle 65. Further, when the on-off valve V2 is closed, the supply of the first chemical solution from the first chemical solution nozzle 65 is stopped.

A chemical solution pipe 81 for feeding a second chemical solution from a second chemical solution supply source 80 is connected to the second chemical solution nozzle 67. The second chemical solution is, for example, a mixture of hydrofluoric acid (HF) and nitric acid (HNO₃), tetramethylammonium hydroxide (TMAH), or hot diluted aqueous ammonia (Hot-dNH₄OH). The chemical solution pipe 81 is provided with an on-off valve V3. The on-off valve V3 allows or stops the supply of the second chemical solution.

A cleaning solution pipe 84 for feeding a first cleaning solution from a first cleaning solution supply source 83 is connected to the first cleaning solution nozzle 69. The first cleaning solution is, for example, SC2 or SPM. SC2 is a mixture of hydrochloric acid (HCl), hydrogen peroxide (H₂O₂), and water. SPM is a mixture of sulfuric acid (H₂SO₄) and a hydrogen peroxide solution (H₂O₂). The cleaning solution pipe 84 is provided with an on-off valve V4. The on-off valve V4 allows or stops the supply of the first cleaning solution.

A cleaning solution pipe 87 for feeding a second cleaning solution from a second cleaning solution supply source 86 is connected to the second cleaning solution nozzle 71. The second cleaning solution is, for example, SC1. SC1 is a mixture of ammonia, a hydrogen peroxide solution (H₂O₂), and water. The cleaning solution pipe 87 is provided with an on-off valve V5. The on-off valve V5 allows or stops the supply of the second cleaning solution.

A rinse solution pipe 90 for feeding a rinse solution from a rinse solution supply source 89 is connected to the rinse solution nozzle 73. The rinse solution is, for example, pure water such as deionized water (DIW) or carbonated water. The rinse solution pipe 90 is provided with an on-off valve V6. The on-off valve V6 allows or stops the supply of the rinse solution.

A gas pipe 93 for feeding gas from a gas supply source 92 is connected to the gas nozzle 75. The gas is an inert gas such as nitrogen. The gas pipe 93 is provided with an on-off valve V7. The on-off valve V7 allows or stops the supply of the gas.

The first chemical solution nozzle 65 is moved in the horizontal direction by a nozzle moving mechanism 95. The nozzle moving mechanism 95 includes an electric motor. The nozzle moving mechanism 95 may rotate the first chemical solution nozzle 65 about a preset vertical axis (not illustrated). Further, the nozzle moving mechanism 95 may move the first chemical solution nozzle 65 in the X direction and the Y direction. Further, the nozzle moving mechanism 95 may move the first chemical solution nozzle 65 in the vertical direction (Z direction). As with the first chemical solution nozzle 65, the five nozzles 67, 69, 71, 73, and 75 may be each moved by a corresponding nozzle moving mechanism (not illustrated).

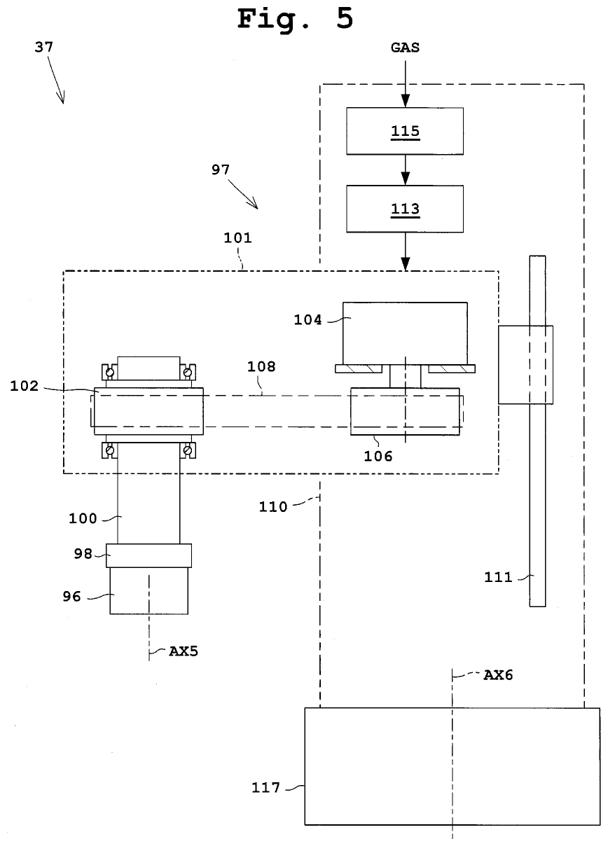

Next, a configuration of the polishing mechanism 37 will be described. The polishing mechanism 37 polishes the back surface of the substrate W. FIG. 5 is a side view of the polishing mechanism 37. The polishing mechanism 37 includes a polishing tool 96 and a polishing tool moving mechanism 97. The polishing tool moving mechanism 97 includes a mount member 98, a shaft 100, and an arm 101.

The polishing tool (grinding tool) 96 polishes the back surface of the substrate W by dry chemo-mechanical grinding (CMG). The polishing tool 96 is formed in a columnar shape. The polishing tool 96 has a resin body in which abrasive grains are dispersed. In other words, the polishing tool 96 is formed of abrasive grains (polishing agent) bound with a resin binder. As the abrasive grains, for example, an oxide such as a cerium oxide or silica is used. It is preferable that the average diameter of the abrasive grains be less than or equal to 10 μm. As the resin body and the resin binder, a thermosetting resin such as an epoxy resin or a phenol resin is used, for example. Alternatively, as the resin body and the resin binder, a thermoplastic resin such as ethyl cellulose may be used, for example. In this case, polishing is performed such that the thermoplastic resin does not become softer.

Here, chemo-mechanical grinding (CMG) will be described. It is considered that grinding based on CMG is achieved by the following principles. That is, the local high temperature and high pressure in the vicinity of the abrasive grains generated by contact between the abrasive grains such as cerium oxide and an object cause a solid phase reaction between the abrasive grains and the object to generate silicates. As a result, a surface layer of the object becomes softer and is then mechanically removed by the abrasive grains. Note that, as for polishing, there is a method called chemical mechanical polishing (CMP). Under this method, a slurry solution is supplied to a pad to be brought into contact with the object to cause surface irregularities of the pad to hold abrasive grains contained in the slurry solution, and then chemical mechanical polishing is performed. The present invention employs CMG.

The polishing tool 96 is detachably attached to the mount member 98 with, for example, a screw. The mount member 98 is fixed to a lower end of the shaft 100. A pulley 102 is fixed to the shaft 100. The shaft 100 has an upper end accommodated in the arm 101. That is, the polishing tool 96 and the mount member 98 are attached to the arm 101 with the shaft 100 interposed therebetween.

An electric motor 104 and a pulley 106 are disposed in the arm 101. The pulley 106 is connected to a rotary output shaft of the electric motor 104. A belt 108 is looped over the two pulleys 102 and 106. The electric motor 104 rotates the pulley 106. The belt 108 transmits the rotation of the pulley 106 to the pulley 102 and the shaft 100. This causes the polishing tool 96 to rotate about a vertical axis AX5.

Furthermore, the polishing tool moving mechanism 97 includes a lifting mechanism 110. The lifting mechanism 110 includes a guide rail 111, an air cylinder 113, and an electro-pneumatic regulator 115. A proximal end of the arm 101 is connected to the guide rail 111 so as to be movable up and down. The guide rail 111 guides the arm 101 in the vertical direction. The air cylinder 113 moves the arm 101 up and down. The electro-pneumatic regulator 115 supplies, to the air cylinder 113, gas such as air that is pressurized on the basis of an electric signal from a main control unit 134 to be described later. Note that the lifting mechanism 110 may include, instead of the air cylinder 113, a linear actuator driven by an electric motor.

The polishing tool moving mechanism 97 further includes an arm rotating mechanism 117. The arm rotating mechanism 117 includes an electric motor. The arm rotating mechanism 117 rotates the arm 101 and the lifting mechanism 110 about a vertical axis AX6. That is, the arm rotating mechanism 117 rotates the polishing tool 96 about the vertical axis AX6.

The polishing unit 22 includes the substrate thickness measuring device 39. The substrate thickness measuring device 39 measures the thickness of the substrate W held by the holding and rotating unit 35. The substrate thickness measuring device 39 is configured to apply, to a mirror and the substrate W, light in a wavelength range (for example, 1100 nm to 1900 nm), the light transmitting the substrate W and being emitted from a light source through an optical fiber. Further, the substrate thickness measuring device 39 is configured to cause a light receiving element to detect return light obtained by interference of light reflected off the mirror, light reflected off the upper surface of the substrate W, and light reflected off the lower surface of the substrate W. The substrate thickness measuring device 39 is configured to generate a spectral interference waveform indicating a relation between a wavelength of the return light and light intensity and analyze the spectral interference waveform to measure the thickness of the substrate W. The substrate thickness measuring device 39 is a known device. The substrate thickness measuring device 39 may be configured to be moved between a standby position outside the substrate and a measuring position above the substrate W by a moving mechanism (not illustrated).

### (1-3) Inspecting Unit 20

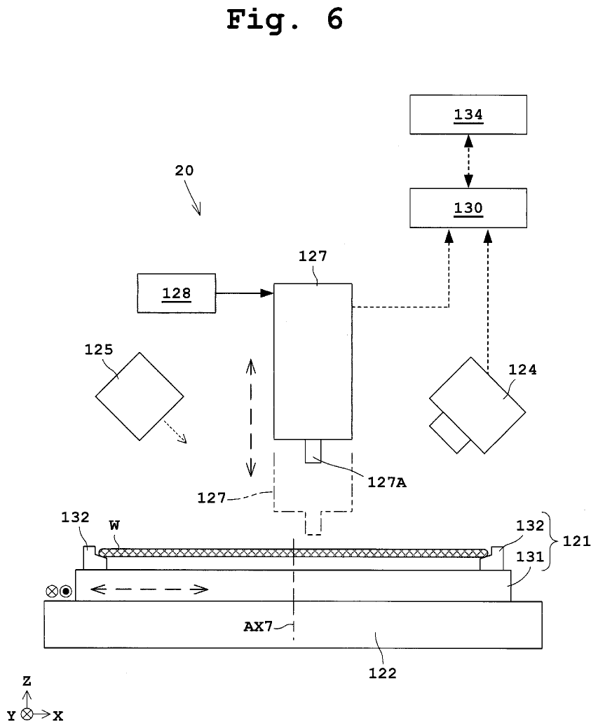

FIG. 6 is a side view of the inspecting unit 20. The inspecting unit 20 includes a stage 121, an XY-direction moving mechanism 122, a camera 124, a lighting device 125, a laser scanning confocal microscope 127, a lifting mechanism 128, and an inspection control unit 130.

The stage 121 supports the substrate W in a horizontal position with the back surface facing upward. The stage 121 includes a base member 131 having a disk shape and, for example, six support pins 132. The six support pins 132 are provided in a ring shape around a center axis AX7 of the base member 131. Further, the six support pins 132 are arranged at equal intervals in a circumferential direction. Such a configuration allows the six support pins 132 to support the outer edge of the substrate W with the substrate W apart from the base member 131. Further, the XY-direction moving mechanism 122 moves the stage 121 in the XY-direction (horizontal direction). The XY-direction moving mechanism 122 includes, for example, two linear actuators each driven by a corresponding electric motor.

The camera 124 captures an image of the back surface of the substrate W. The camera 124 includes an image sensor such as a charge-coupled device (CCD) or a complementary metal-oxide semiconductor (CMOS). The lighting device 125 applies light to the back surface of the substrate W. This allows, for example, a scratch generated on the back surface of the substrate W to be easily observed.

The laser scanning confocal microscope 127 is hereinafter referred to as “laser microscope 127”. The laser microscope 127 includes a laser light source, an objective lens 127A, an imaging lens, an optical sensor, and a confocal optical system having a confocal pinhole. The laser microscope 127 acquires a two-dimensional image by causing the laser light source to scan in the XY direction (horizontal direction). The laser microscope 127 further acquires a two-dimensional image while moving the objective lens 127A in the Z direction (height direction) relative to an observation target. As a result, the laser microscope 127 acquires a three-dimensional image (a plurality of two-dimensional images) capturing a three-dimensional shape. Note that the laser microscope 127 is referred to as three-dimensional shape measurement device.

The laser microscope 127 acquires a three-dimensional image of any scratch generated on the back surface of the substrate W. For example, the control unit to be described later measures a depth of the scratch from a three-dimensional shape of the scratch appearing in the acquired three-dimensional image. The lifting mechanism 128 moves the laser microscope 127 up and down in the vertical direction (Z direction). The lifting mechanism 128 includes a linear actuator driven by an electric motor.

The inspection control unit 130 includes one or a plurality of processors such as a central processing unit (CPU) and a storage unit (not illustrated). The inspection control unit 130 controls each component of the inspecting unit 20. The storage unit of the inspection control unit 130 includes at least one of a read-only memory (ROM), a random-access memory (RAM), or a hard disk. The storage unit of the inspection control unit 130 stores a computer program to operate the inspecting unit 20, an observation image, a scratch extraction result, and a three-dimensional image.

The substrate processing device 1 further includes the main control unit 134 and a storage unit (not illustrated) communicatively connected to the inspection control unit 130. The main control unit 134 includes one or a plurality of processors such as a central processing unit (CPU). The main control unit 134 controls each component of the substrate processing device 1. Further, the storage unit of the main control unit 134 includes at least one of a read-only memory (ROM), a random-access memory (RAM), or a hard disk. The storage unit of the main control unit 134 stores a computer program to operate the substrate processing device 1, and the like.

### (2) Operation of Substrate Processing Device 1

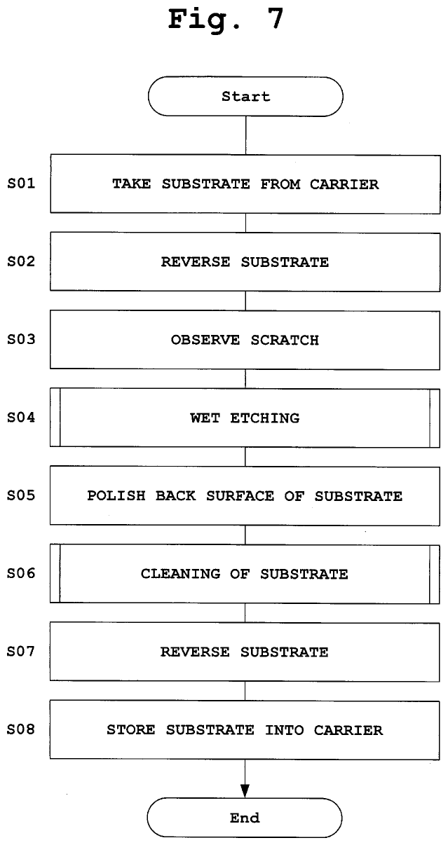

Next, how the substrate processing device 1 operates will be described with reference to FIG. 7.

### [Step S01] Taking Substrate W From Carrier C

Each carrier C is loaded onto a predetermined carrier loading table 7. The indexer robot 9 takes the substrate W from the carrier C and conveys the substrate W thus taken to the reversing unit RV. At this time, the device surface of the substrate W faces upward, and the back surface of the substrate W faces downward.

### [Step S02] Reversal of Substrate W

After the indexer robot 9 loads one or two substrates W onto the loading members 28A and 28B, the reversing unit RV reverses the two substrates W as illustrated in FIGS. 2A to 2D. This causes the back surface of each substrate W to face upward.

The substrate conveying robot CR takes the substrate W from the reversing unit RV and conveys the substrate W to one of two inspecting units 20. The substrate W having its back surface facing upward is loaded onto the stage 121 of the inspecting unit 20 illustrated in FIG. 6.

### [Step S03] Scratch Observation

The inspecting unit 20 inspects the back surface of the substrate W. The inspecting unit 20 detects a scratch, a particle, or any other protrusion. In particular, a case where a scratch formed on the back surface of the substrate W is detected will be described in the present embodiment.

In the inspecting unit 20 illustrated in FIG. 6, the lighting device 125 applies light to the back surface of the substrate W. The camera 124 captures an image of the back surface of the substrate W to which light is applied to acquire an observation image. The camera 124 may capture an image while the XY-direction moving mechanism 122 moves the stage 121 on which the substrate W is loaded. Large and small scratches appear in the observation image thus acquired. The inspection control unit 130 performs image processing on the observation image, and extracts one or a plurality of scratches by regarding a portion where the reflected light is relatively strong, that is, a portion higher in luminance than a preset threshold as a polishing target. Alternatively, the inspection control unit 130 may extract a scratch as a polishing target on the basis of the length of the scratch.

Further, when detecting a scratch, the inspecting unit 20 measures the depth of the scratch. For example, when detecting (extracting) a plurality of scratches, the inspecting unit 20 measures the depth of one or a plurality of representative scratches. How to measure the scratch depth will be described.

The lifting mechanism 128 (FIG. 6) moves the laser microscope 127 down to a preset height position. In addition, the XY-direction moving mechanism 122 moves the stage 121 so as to position a scratch to be measured below the objective lens 127A of the laser microscope 127. The stage 121 is moved on the basis of coordinates of the scratch extracted from the observation image. The laser microscope 127 applies, to (the whole or part of) the scratch and an area around the scratch, laser light from the objective lens 127A and collects reflected light through the objective lens 127A. As a result, the laser microscope 127 acquires a three-dimensional image capturing a three-dimensional shape.

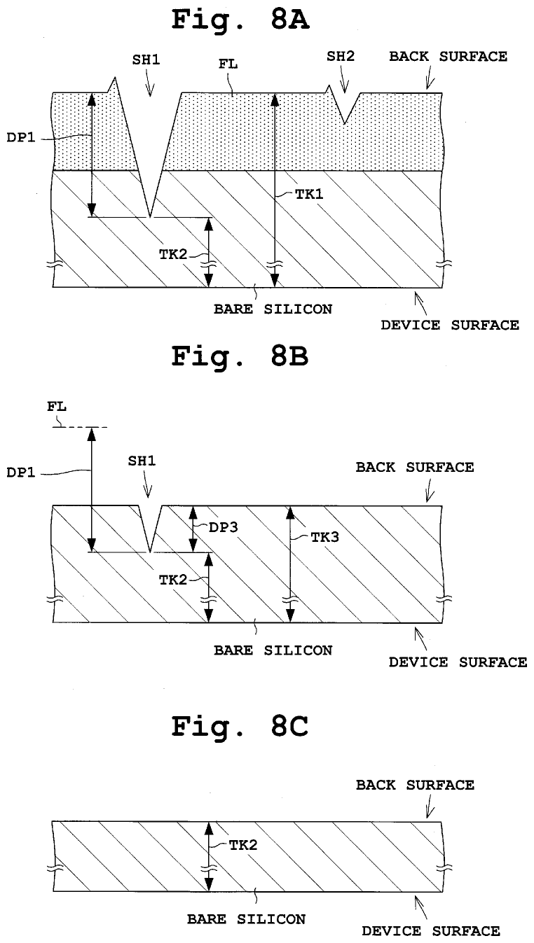

The inspection control unit 130 performs image processing on the three-dimensional image to measure the depth of the scratch. FIG. 8A is a longitudinal cross-sectional view of the substrate W before being subjected to an etching process for describing a state of the substrate W. In FIG. 8A, for example, a thin film such as a silicon oxide film, a silicon nitride film, or polysilicon is formed on the back surface of the substrate W. Further, it is assumed that a scratch SHI located on the left side of FIG. 8A reaches bare silicon BSi. In this case, the inspection control unit 130 measures a depth (value DP1) of the scratch SH1 from a three-dimensional image obtained by the laser microscope 127.

After the observation of the scratch and the like, the substrate conveying robot CR conveys the substrate W from the stage 121 of the inspecting unit 20 to any one of the six polishing units 22 (U2 to U4). The substrate W having its back surface facing upward is loaded onto the holding and rotating unit 35 of the polishing unit 22. Thereafter, the magnet (not illustrated) rotates the three holding pins 43A illustrated in FIG. 4A around the rotation axis AX4. This causes the three holding pins 43A to hold the substrate W. Here, the substrate W is held with the substrate W apart from the spin base 41 and the hot plate 45.

Here, before the next wet etching process, the substrate thickness measuring device 39 measures the thickness of the substrate W. A thickness TK1 of the substrate Was illustrated in FIG. 8A is acquired.

### [Step S04] Wet Etching

When a thin film such as a silicon oxide film, a silicon nitride film, or a polysilicon film is formed on the back surface of the substrate W, the back surface of the substrate W cannot be satisfactorily polished by the polishing tool 96. Such films include a film unintentionally formed during a device manufacturing process and a film intentionally formed to suppress warpage of the substrate W. Therefore, the polishing unit 22 removes a film F1 formed on the back surface of the substrate W by supplying the first chemical solution (etching solution) to the back surface of the substrate W.

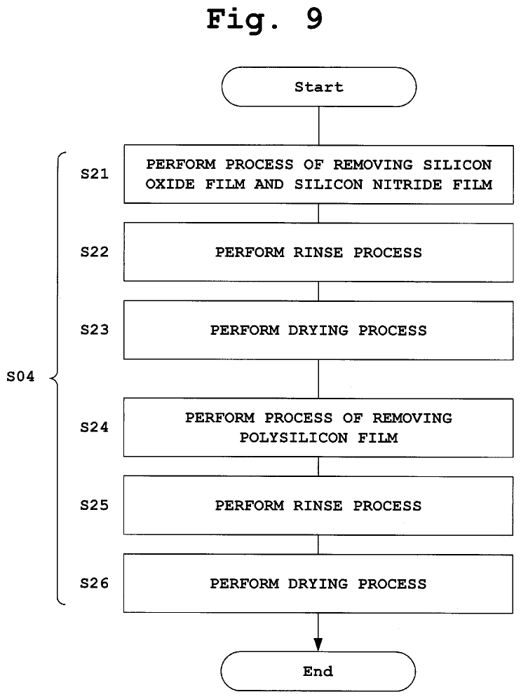

FIG. 9 is a flowchart for describing the wet etching process in step S04 in detail. First, a process of removing the silicon oxide film and the silicon nitride film is performed (step S21).

Here, gas is discharged from the gas discharge port 47 provided at the center of the spin base 41. That is, from the gas discharge port 47, the gas is discharged so as to flow from the center side of the substrate W toward the outer edge of the substrate through a gap between the substrate W and the spin base 41. The device surface (front surface) of the substrate W faces the spin base 41. When the gas is discharged from the gas discharge port 47, the gas flows out from a gap between the outer edge of the substrate W and the spin base 41. For example, a polishing residue or a solution such as the first chemical solution is prevented from adhering to the device surface of the substrate W. That is, the device surface can be protected. Further, due to the Bernoulli's effect, a force of attracting the substrate W to the spin base 41 acts.

The nozzle moving mechanism 95 moves the first chemical solution nozzle 65 from the standby position outside the substrate to any desired processing position above the substrate W. The holding and rotating unit 35 rotates the substrate W while holding the substrate W in a horizontal position. Thereafter, the first chemical solution (for example, hydrofluoric acid) is supplied from the first chemical solution nozzle 65 to the back surface of the rotating substrate W. This allows the silicon oxide film and the silicon nitride film formed on the back surface of the substrate W to be removed.

Note that the first chemical solution may be supplied with the first chemical solution nozzle 65 being continuously moved in the horizontal direction. Further, after the supply of the first chemical solution from the first chemical solution nozzle 65 is stopped, the first chemical solution nozzle 65 is moved to the standby position outside the substrate.

Thereafter, a rinse process is performed (step S22). That is, the rinse solution (for example, DIW or carbonated water) is supplied from the rinse solution nozzle 73 to the center of the rotating substrate W. This causes the first chemical solution remaining on the back surface of the substrate W to be washed away from the substrate. Thereafter, a drying process is performed (step S23). That is, the supply of the rinse solution from the rinse solution nozzle 73 is stopped. Then, the holding and rotating unit 35 rotates the substrate W at a high speed to dry the substrate W. At this time, gas may be supplied to the back surface of the substrate W from the gas nozzle 75 moved above the substrate W. Note that the drying process may be performed by supplying gas from the gas nozzle 75 without rotating the substrate W at a high speed.

After steps S21 to S23, a process of removing the polysilicon film is performed (step S24). The second chemical solution nozzle 67 is moved from the standby position outside the substrate to any desired processing position above the substrate W. The holding and rotating unit 35 rotates the substrate W at a preset rotation speed. Thereafter, the second chemical solution (for example, a mixture of hydrofluoric acid (HF) and nitric acid (HNO₃)) is supplied from the second chemical solution nozzle 67 to the back surface of the rotating substrate W. This allows the polysilicon film formed on the back surface of the substrate W to be removed.

The second chemical solution may be supplied with the second chemical solution nozzle 67 being continuously moved in the horizontal direction. Further, after the supply of the second chemical solution from the second chemical solution nozzle 67 is stopped, the second chemical solution nozzle 67 is moved to the standby position outside the substrate.

Thereafter, the rinse process (step S25) is performed in a manner similar to a case of the first chemical solution (steps S22 and S23), and then the drying process (step S26) is performed. The holding and rotating unit 35 stops the rotation of the substrate W.

### [Step S05] Polishing of Back Surface of Substrate W

After the etching process, the polishing unit 22 polishes the back surface of the substrate W. This polishing is performed particularly when the inspecting unit 20 detects a scratch on the back surface of the substrate W. A specific description will be given below.

The holding and rotating unit 35 rotates the substrate W with the substrate W held in a horizontal position. The arm rotating mechanism 117 (FIG. 5) of the polishing mechanism 37 rotates the polishing tool 96 and the arm 101 about the vertical axis AX6. This causes the polishing tool 96 to move from the standby position outside the substrate to a preset position above the substrate W. Further, the electric motor 104 of the polishing mechanism 37 rotates the polishing tool 96 about the vertical axis AX5 (shaft 100).

Further, the hot plate 45 is energized to generate heat, which heats the substrate W. The temperature of the substrate W is monitored by the temperature sensor 46 of a noncontact type. The main control unit 134 regulates the heat generated by the hot plate 45 on the basis of the temperature of the substrate W detected by the temperature sensor 46. A temperature to which the substrate W is heated is regulated to a temperature higher than room temperature (for example, 25° C.) in order to make a polishing rate higher. Note that it is preferable that the temperature be regulated to be less than or equal to 100° C. in order to avoid thermal deterioration of the polishing tool 96.

Thereafter, the electro-pneumatic regulator 115 supplies, to the air cylinder 113, gas pressurized on the basis of the electric signal. The air cylinder 113 moves the polishing tool 96 and the arm 101 down to bring the polishing tool 96 into contact with the back surface of the substrate W. The polishing tool 96 is pressed against the back surface of the substrate W at preset contact pressure. Accordingly, polishing is performed. When polishing is performed, the arm rotating mechanism 117 (FIG. 5) of the polishing mechanism 37 swings the polishing tool 96 and the arm 101 around the vertical axis AX6. That is, the polishing tool 96 is repeatedly moved between the center and the outer edge of the back surface of the substrate W.

Note that, regarding the amount of polishing of the substrate W in the thickness direction (Z direction), polishing seems unnecessary as long as the substrate W satisfies preset flatness even if there is a scratch. The edge of the scratch may, however, generate a new scratch on a stage of a lithography machine, for example. Therefore, polishing is performed until there is no scratch having a preset size.

As illustrated in FIG. 8A, the depth (value DP1) of the scratch SH1 is acquired by the laser microscope 127. Therefore, the polishing unit 22 polishes the back surface of the substrate W to make the substrate W thinner by the thickness corresponding to the depth (value DP1) of the scratch SH1 measured by the laser microscope 127. The thickness corresponding to the depth of the scratch SH1 is the value DP1. Polishing is performed until the thickness of the substrate W reaches a value TK2(=TK1−DP1). The thickness of the substrate W is periodically measured by the substrate thickness measuring device 39. The main control unit 134 compares the measured value of the thickness of the substrate with a target value (for example, the value TK2), and if the measured value has not reached the target value, controls to continue polishing.

Note that FIG. 8B is a diagram illustrating a state after the etching process (step S04). When the film FL is removed by the etching process, the scratch SH1 becomes shallower. Therefore, the polishing amount in the vertical direction decreases, but it is still necessary to perform polishing until the thickness of the substrate W reaches the value TK2. FIG. 8C is a diagram illustrating a state after the polishing process (step S05). Note that a scratch SH2 illustrated in FIG. 8A does not reach bare silicon. Such a scratch is removed when the film FL such as a silicon oxide film is removed.

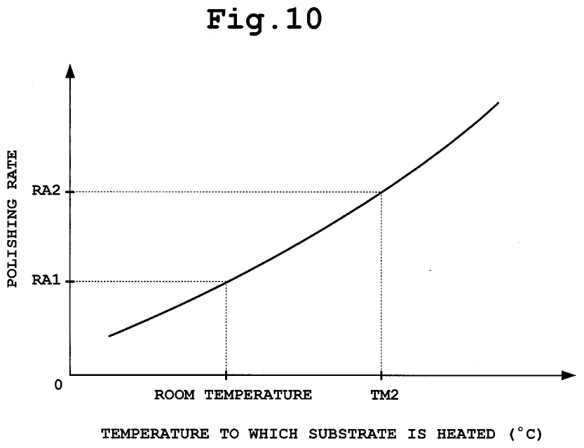

The substrate W is heated by the hot plate 45. FIG. 10 is a diagram illustrating a relation between the temperature to which the substrate W is heated and the polishing rate. The contact pressure applied to the polishing tool 96, the rotation speed of the substrate W, and the like are constant. Here, for example, as compared with a case where the temperature of the substrate W is room temperature (for example, 25° C.), if a temperature TM2 of the substrate W is increased, the polishing rate increases. It is therefore possible to increase the polishing rate by heating the substrate W with the hot plate 45. It is therefore possible to reduce the time taken for the polishing process.

When performing polishing, the polishing unit 22 may regulate the polishing rate by controlling the temperature to which the substrate W is heated by the hot plate 45. Increasing or decreasing the temperature to which the substrate W is heated allows an increase or decrease in the polishing rate. The polishing rate may be regulated before polishing or during polishing. For example, it is possible to make the polishing rate different between the center of the substrate W and the outer edge of the substrate W by changing the temperature of the substrate W between the center of the substrate W and the outer edge of the substrate W. Note that the polishing tool 96 is moved to the standby position of the substrate W.

### [Step S06] Cleaning of Substrate W

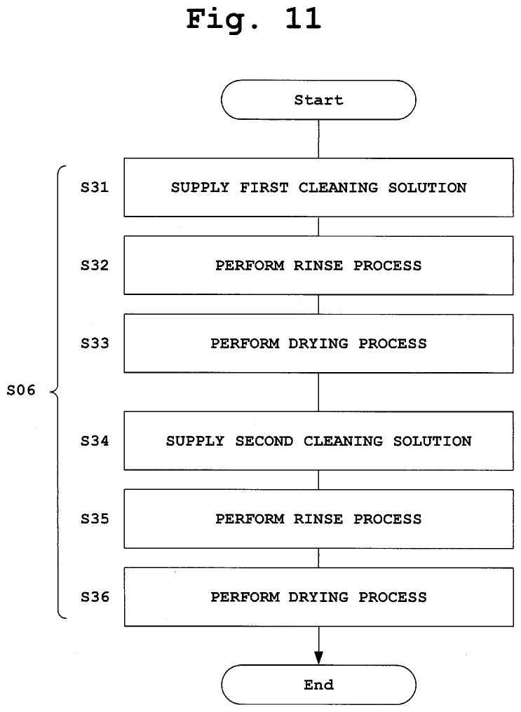

After the back surface of the substrate W is polished, the back surface of the substrate W is cleaned. This removes not only a polishing residue remaining on the back surface of the substrate W but also metal, organic substances, and particles. FIG. 11 is a flowchart illustrating details of the cleaning process in step S06.

First, the first cleaning solution is supplied to the back surface of the substrate W (step S31). A specific description will be given below. The holding and rotating unit 35 continues to hold the substrate W. Further, the holding and rotating unit 35 discharges gas from the gas discharge port 47 to continue to protect the device surface of the substrate W. The first cleaning solution nozzle 69 is moved from the standby position outside the substrate to any desired processing position above the substrate W. The holding and rotating unit 35 rotates the substrate W. Thereafter, the first cleaning solution (for example, SC2 or SPM) is supplied from the first cleaning solution nozzle 69 to the back surface of the rotating substrate W. The first cleaning solution may be supplied with the first cleaning solution nozzle 69 being continuously moved in the horizontal direction.

After the first cleaning solution is supplied and the cleaning process is performed, the rinse process is performed (step S32). That is, the rinse solution (DIW or carbonated water) is supplied from the rinse solution nozzle 73 to the center of the rotated substrate W. This causes the first cleaning solution remaining on the back surface of the substrate W to be washed away. Thereafter, the drying process is performed (step S33). That is, the supply of the rinse solution from the rinse solution nozzle 73 is stopped. Then, the holding and rotating unit 35 rotates the substrate W at a high speed to dry the substrate W. At this time, gas may be supplied to the back surface of the substrate W from the gas nozzle 75 moved above the substrate W. Note that the drying process may be performed by supplying gas from the gas nozzle 73 without rotating the substrate W at a high speed.

After steps S31 to S33, the second cleaning solution is supplied (step S34). That is, the second cleaning solution nozzle 71 is moved from the standby position outside the substrate to any desired processing position above the substrate W. The holding and rotating unit 35 rotates the substrate W at a preset rotation speed. Thereafter, the second cleaning solution (for example, SC1) is supplied from the second cleaning solution nozzle 71 to the back surface of the rotating substrate W.

The second cleaning solution may be supplied with the second cleaning solution nozzle 71 being continuously moved in the horizontal direction. After the supply of the second cleaning solution from the second cleaning solution nozzle 71 is stopped, the second cleaning solution nozzle 71 is moved to the standby position outside the substrate.

Thereafter, the rinse process (step S35) is performed in a manner similar to a case of the first cleaning solution (steps S32 and S33), and then the drying process (step S36) is performed. The holding and rotating unit 35 stops the rotation of the substrate W. The polishing unit 22 according to the present embodiment has a cleaning function, so that the substrate W cleaned of a polishing residue can be carried out from the polishing unit 22.

### [Step S07] Reversal of Substrate W

The substrate conveying robot CR takes the substrate W from the polishing unit 22 and conveys the substrate W to the reversing unit RV. At this time, the back surface of the substrate W faces upward, and the device surface of the substrate W faces downward. After the substrate conveying robot CR loads one or two substrates W onto the loading members 28A and 28B, the reversing unit RV reverses the two substrates W as illustrated in FIGS. 2A to 2D. This causes the back surface of each substrate W to face downward.

### [Step S08] Storage of Substrate W Into Carrier C

The indexer robot 9 takes the substrate W from the reversing unit RV and returns the substrate W to the carrier C.

According to the present embodiment, the polishing unit 22 includes the holding and rotating unit 35, the hot plate 45 (heating means), and the polishing tool 96. The polishing tool 96 comes into contact with the back surface of the rotating substrate W to polish the back surface of the substrate W by chemo-mechanical grinding (CMG). When this polishing is performed, the substrate W is heated by the hot plate 45. Heating the substrate W allows an increase in the polishing rate (see FIG. 10). It is therefore possible to reduce the time taken for the polishing process.

Further, the inspecting unit 20 that inspects the substrate W detects a scratch formed on the back surface of the substrate W before polishing the back surface of the substrate W. Further, when detecting a scratch, the inspecting unit 20 polishes the back surface of the substrate W. This makes it possible to remove the detected scratch, that is, a selected scratch by polishing.

Further, when detecting a scratch, the inspecting unit 20 measures the depth of the scratch. The polishing unit 22 polishes the back surface of the substrate W to make the substrate W thinner by the thickness corresponding to the depth of the scratch measured by the inspecting unit 20. As a result, the depth of the scratch is recognized, so that it is possible to make the amount of polishing of the substrate W in the thickness direction optimum.

### (1-4) Polishing Head 201

Here, a preferable configuration of the above-described polishing mechanism 37 will be described with reference to FIG. 12. FIG. 12 is a diagram illustrating a preferable configuration of the polishing mechanism of the polishing unit.

This polishing mechanism 37A is different from the above-described polishing mechanism 37 in the following points.

A polishing head 201 is attached to the mount member 98. The polishing head 201 includes the polishing tool 96.

The shaft 100 to which the mount member 98 is attached is provided with a gas supply pipe 203 and a suction pipe 205. The gas supply pipe 203 and the suction pipe 205 are provided in the shaft 100 in parallel to each other. The gas supply pipe 203 and the suction pipe 205 extend through the shaft 100. The gas supply pipe 203 and the suction pipe 205 communicate with and are connected to a rotary joint 207. The rotary joint 207 includes a fixed-side body 209 and a rotating-side body 211. The fixed-side body 209 is fixed to the arm 101. The rotating-side body 211 is attached to the shaft 100. The rotary joint 207 allows at least two fluids to flow between the fixed-side body 209 fixed to the arm 101 and the rotating-side body 211 rotating together with the shaft 100.

The gas supply pipe 203 extending from the rotary joint 207 has one end communicatively connected to a gas supply source 213. The gas supply source 213 supplies gas. The gas is preferably an inert gas. The inert gas is, for example, a nitrogen gas. The gas supply pipe 203 includes a flow rate regulating valve 215 and an on-off valve 217. The flow rate regulating valve 215 regulates the flow rate of gas flowing through the gas supply pipe 203. The on-off valve 217 allows or blocks the flow of gas through the gas supply pipe 203.

The suction pipe 205 extending from the rotary joint 207 has one end communicatively connected to a suction source 219. The suction source 219 performs suctioning of the inside of the suction pipe 205. The suction source 219 sucks gas. The suction source 219 is, for example, a suction pump or a utility for suction provided in a clean room. The suction pipe 205 includes an on-off valve 221. The on-off valve 221 allows or blocks the flow of gas through the suction pipe 205.

The on-off valves 217 and 221 and the flow rate regulating valve 215 described above are operated by the main control unit 134.

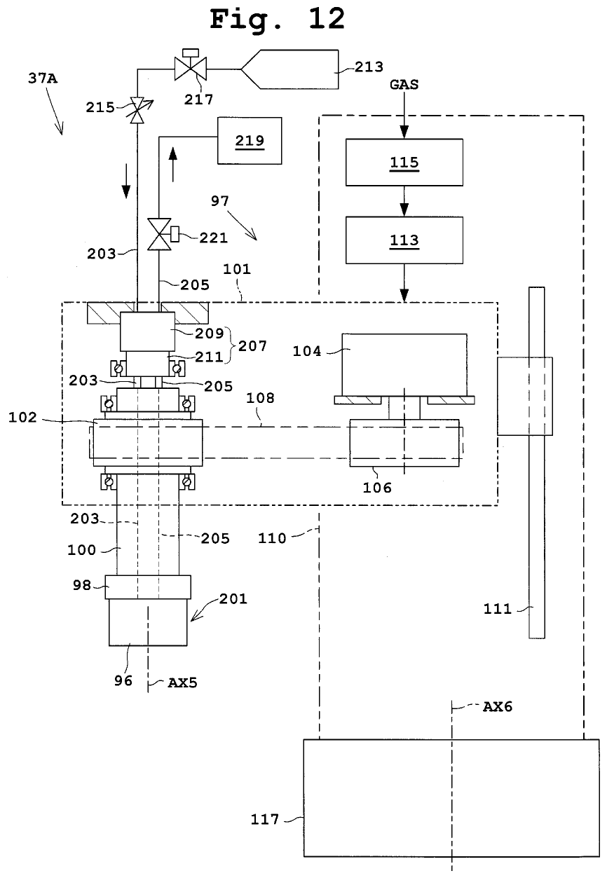

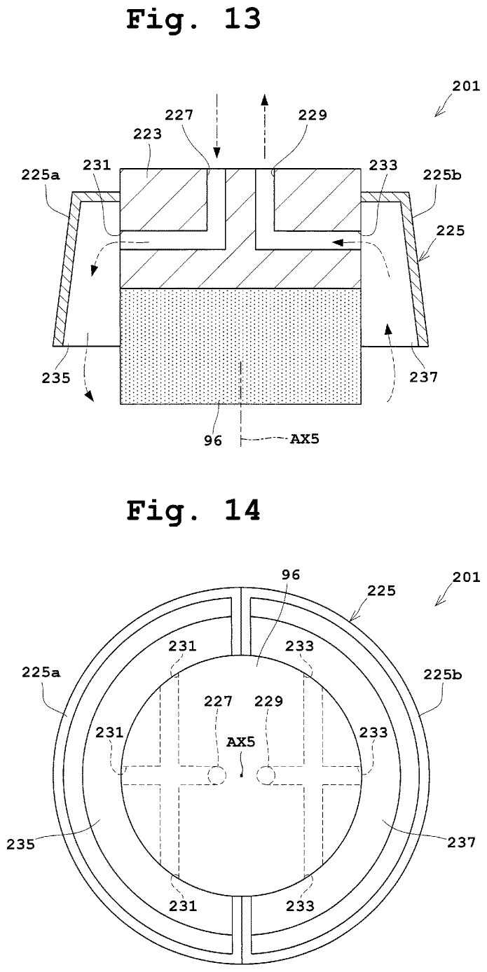

Refer now to FIGS. 13 and 14. FIG. 13 is a longitudinal cross-sectional view of the polishing head according to the first embodiment. FIG. 14 is a bottom view of the polishing head according to the first embodiment.

The polishing head 201 includes the polishing tool 96, a head body 223, and a cover 225. The polishing tool 96 is attached to a lower surface of the head body 223. The head body 223 includes a first flow path 227 and a second flow path 229. The first flow path 227 and the second flow path 229 do not communicate with each other. The first flow path 227 and the second flow path 229 communicatively connect an upper surface and an outer peripheral surface of the head body 223. The first flow path 227 has an opening 231 formed at three places on the outer peripheral surface of the head body 223, for example. The second flow path 229 has an opening 233 formed at three places on the outer peripheral surface of the head body 223, for example. It is preferable that the first flow path 227 and the second flow path 229 be formed to be line-symmetric with respect to a straight line passing through the vertical axis AX5 as viewed from above.

The cover 225 is attached to the head body 223. The cover 225 is attached to the outer peripheral surface of the head body 223. The cover 225 has a shape with a horizontally extending portion and a portion inclined outward from the horizontally extending portion, for example. In other words, the cover 225 has a trapezoidal shape. The cover 225 has a lower end located higher than a lower surface of the polishing tool 96. This is to prevent the cover 225 from coming into contact with the substrate W even if the polishing tool 96 wears. The cover 225 includes a first cover 225a and a second cover 225b. The first cover 225a and the second cover 225b are formed to be line-symmetric with respect to the straight line passing through the vertical axis AX5 as viewed from above.

The first cover 225a covers sides of the openings 231. The second cover 225b covers sides of the openings 233. The first cover 225a has a lower portion serving as an ejection port 235. The second cover 225b has a lower portion serving as a suction port 237. The ejection port 235 is provided along a half of the outer peripheral surface of the polishing tool 96. The suction port 237 is provided along the other half of the outer peripheral surface of the polishing tool 96. The suction port 237 and the ejection port 235 are formed to be line-symmetric with respect to the straight line passing through the vertical axis AX5 as viewed from above.

In the polishing head 201, the first flow path 227 is communicatively connected to the other end of the gas supply pipe 203. In the polishing head 201, the second flow path 229 is communicatively connected to the other end of the suction pipe 205. In other words, the ejection port 235 communicates with the gas supply source 213. The suction port 237 communicates with the suction source 219.

The polishing unit 22 configured as described above polishes the substrate W as follows, for example. Note that how the arm 101 and the like operate is as described above.

The main control unit 134 performs an operation related to supply and suction of gas. Specifically, the main control unit 134 sets the flow rate regulating valve 215 to a predetermined supply flow rate in advance. The predetermined supply flow rate is preferably set within a range not exceeding the flow rate of suction from the suction pipe 205. The main control unit 134 opens the on-off valves 217 and 221 in synchronization with or slightly earlier than the start of the polishing process. This causes the nitrogen gas to be supplied to the gas supply pipe 203 at the predetermined supply flow rate and causes the gas to be sucked through the suction pipe 205.

Note that the polishing tool moving mechanism 97 described above corresponds to a “head drive mechanism” according to the present invention. The polishing unit 22 described above corresponds to a “polishing device” according to the present invention. The flow rate regulating valve 215 and the on-off valve 217 described above correspond to a “control valve”according to the present invention. The main control unit 134 described above corresponds to a “control unit” according to the present invention.

According to the present embodiment, dust particles generated on the back surface of the substrate W as a result of polishing by the polishing tool 96 rotating about the vertical axis AX5 are also forced out toward the outer periphery of the polishing tool 96 by centrifugal force. Then, nitrogen gas is ejected from the ejection port 235. This forces the dust particles adhering to the back surface of the substrate W to separate from the back surface of the substrate W. The dust particles are sucked through the suction port 237. This makes the dust particles less likely to remain on the back surface of the substrate W, so that it is possible to increase the rate of removal of the dust particles generated as a result of polishing.

Furthermore, according to the present embodiment, the outer peripheral surface of the polishing tool 96 is divided in line symmetry as viewed from above, and the resultant surfaces are used as the ejection port 235 and the suction port 237. This makes it possible to keep a balance between supply and suction of the nitrogen gas on the outer peripheral surface of the polishing tool 96 satisfactory. It is therefore possible to remove the dust particles satisfactorily.

Further, according to the present embodiment, the flow rate of the nitrogen gas from the ejection port 235 is set so as not to exceed the suction flow rate. It is therefore possible to prevent a situation where the nitrogen gas ejected from the ejection port 235 prevents the dust particles from being sucked from the suction port 237 and causes the dust particles to scatter around.

Note that it is preferable that the main control unit 134 operate the flow rate regulating valve 215 to make the flow rate of the nitrogen gas variable over time. The flow rate in this case also includes a flow rate 0 at which the nitrogen gas is not supplied. This makes the flow rate of the nitrogen gas ejected from the ejection port 235 variable. In other words, the supply of the nitrogen gas is not constant but is discontinuous or intermittent. Further, the main control unit 134 may operate the on-off valve 217 to open or close the on-off valve 217 without operating the flow rate regulating valve 215 to keep the opening degree of the flow rate regulating valve 215 constant. As a result, the nitrogen gas is ejected discontinuously or intermittently from the ejection port 235.

When the nitrogen gas is continuously ejected, the dust particles are pressed against the back surface of the substrate W, which possibly prevents the dust particles from being smoothly sucked and removed. Therefore, the main control unit 134 operates the flow rate regulating valve 215 or the on-off valve 217 to make the ejection of the nitrogen gas from the polishing head 201 discontinuous. When the nitrogen gas is discontinuously and intermittently ejected, the pressing force produced by the nitrogen gas becomes temporarily weak, thereby allowing the dust particles to be easily removed.

### Second Embodiment

Hereinafter, a second embodiment of the present invention will be described with reference to the drawings. Note that a configuration except for a polishing head 201A is the same as in the above-described embodiment.

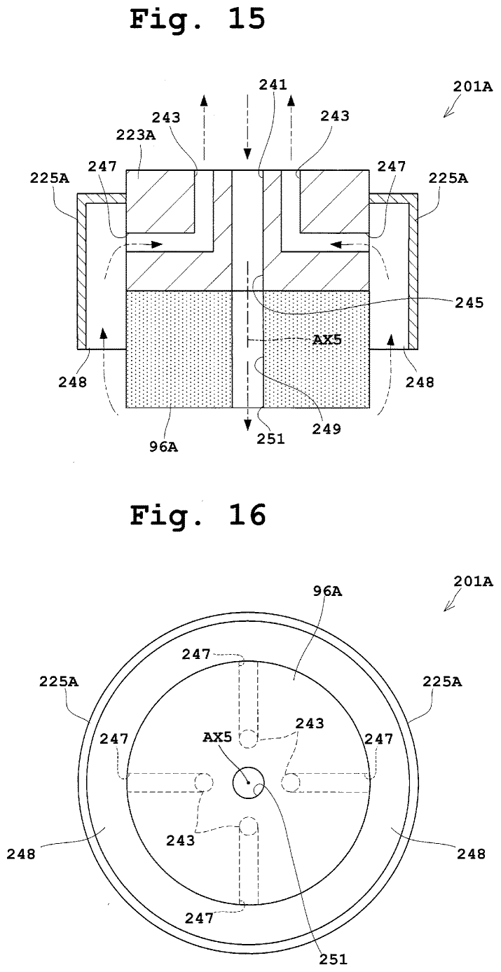

Refer to FIGS. 15 and 16. FIG. 15 is a longitudinal cross-sectional view of a polishing head according to the second embodiment. FIG. 16 is a bottom view of the polishing head according to the second embodiment.

The polishing head 201A includes a polishing tool 96A, a head body 223A, and a cover 225A. The polishing tool 96A is attached to a lower surface of the head body 223A. In the head body 223A, a first flow path 241 and a second flow path 243 are formed. The first flow path 241 and the second flow path 243 do not communicate with each other. The first flow path 241 has an opening 245 formed on the lower surface of the head body 223A. The first flow path 241 almost coincides with the vertical axis AX5. The second flow path 243 communicatively connects an upper surface and an outer peripheral surface of the head body 223A. The second flow path 243 has an opening 247 formed at four places on the outer peripheral surface of the head body 223A, for example. The second flow path 243 also communicates with the upper surface of the head body 223A at four places, for example. It is preferable that the openings 247 of the second flow path 243 be located at equiangular intervals as viewed from above. This allows uniform suction.

The cover 225A is attached to the head body 223A. The cover 225A is attached to the outer peripheral surface of the head body 223A. The cover 225A has a shape with a horizontally presented portion and a portion extending downward from the horizontally presented portion, for example. The cover 225A has a lower end located higher than a lower surface of the polishing tool 96A. The cover 225A has a lower portion serving as a suction port 248.

The polishing tool 96A has a through hole 249 formed at the center of the polishing tool 96A. The polishing tool 96A has an annular shape as viewed from above. The through hole 249 almost coincides with the vertical axis AX5 as viewed from above. The through hole 249 coincides with the first flow path 241 as viewed from above. The through hole 249 communicates with the first flow path 241. An opening of the through hole 249 communicating with the lower surface of the polishing tool 96A serves as an ejection port 251.

In the polishing head 201A, the first flow path 241 is communicatively connected to the other end of the gas supply pipe 203. In the polishing head 201A, the second flow path 243 is communicatively connected to the other end of the suction pipe 205. In other words, the ejection port 251 communicates with the gas supply source 213. The suction port 248 communicates with the suction source 219.

According to the present embodiment, the nitrogen gas ejected from the center of the polishing tool 96A flows toward the outer periphery of the polishing tool 96A along the back surface of the substrate W. It is therefore possible to efficiently suck the nitrogen gas containing the dust particles through the suction port 248.

### Third Embodiment

Hereinafter, a third embodiment of the present invention will be described with reference to the drawings. Note that a configuration except for a polishing head 201B is the same as in the above-described embodiments.

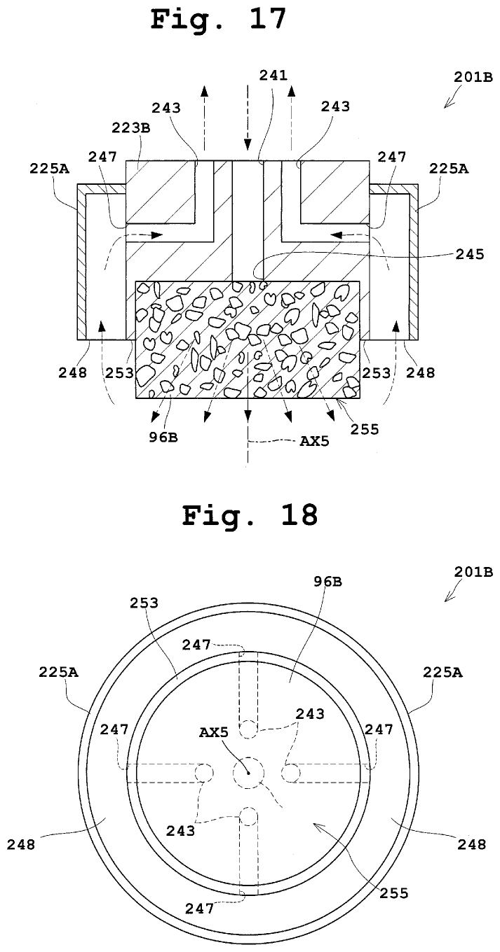

Refer to FIGS. 17 and 18. FIG. 17 is a longitudinal cross-sectional view of a polishing head according to the third embodiment. FIG. 18 is a bottom view of the polishing head according to the third embodiment.

The polishing head 201B includes a polishing tool 96B, a head body 223B, and a cover 225A. The polishing tool 96B is attached to a lower surface of the head body 223B. In the head body 223B, a first flow path 241 and a second flow path 243 are formed. The first flow path 241 and the second flow path 243 are the same as in the second embodiment described above. In the head body 223B, an edge portion 253 is formed. An edge portion of the lower surface of the head body 223B protrudes downward to form the edge portion 253. The polishing unit 96B is attached to the edge portion 253.

The polishing tool 96B is formed of a porous member. In the polishing tool 96B, a large number of small holes are formed. In the polishing tool 96B, the large number of holes are communicatively connected to each other. Nitrogen gas supplied from the first flow path 241 is ejected from the lower surface of the polishing tool 96B to the back surface of the substrate W through the large number of small holes of the polishing tool 96B. In other words, the lower surface of the polishing tool 96B serves as an ejection port 255.

The cover 225A has the same configuration as in the second embodiment described above and has its lower portion serving as a suction port 248.

According to the present embodiment, the nitrogen gas can be supplied to the polishing tool 96B formed of a porous member, and the nitrogen gas can be ejected toward the dust particles from the ejection port 255 corresponding to almost the entire lower surface of the polishing tool 96B. It is therefore possible to efficiently force the dust particles out toward the outer periphery.

The present invention is not limited to the above-described embodiments, and may be modified as follows.
(1) In each of the above-described embodiments, suction is performed through the suction port 237, 248 having a wide opening formed in the cover 225, 225A. The present invention, however, is not limited to such a configuration. For example, a piping structure in which a pipe having one end communicating with the opening 233, 247 of the head body 223 (223A, 223B) and having the other end facing the surface to be polished may be employed.
(2) Each of the above-described embodiments has a configuration where nitrogen gas is ejected from the ejection port. In the present invention, however, the gas is not limited to nitrogen gas. For example, argon gas may be used as the gas.
(3) In each of the above-described embodiments, the gas supply pipe 203 and the suction pipe 205 are arranged in parallel. The present invention, however, is not limited to such a configuration. For example, a configuration where a double tube is inserted through the shaft 100 and used for gas supply and suction may be employed.
(4) In each of the above-described embodiments, the main control unit 134 operates the flow rate regulating valve 215 to make the flow rate of nitrogen gas variable over time, but the present invention does not necessarily require such an operation. That is, the flow rate of nitrogen gas may be kept constant during the polishing process.
(5) In each of the above-described embodiments, the polishing head 201, 201A, 201B is configured to be detachably attached to the mount member 98. The polishing head 201, 201A, 201B, however, may be semi-fixed to the mount member 98, and only the polishing tools 96, 96A, 96B may be detachable and easily replaceable.
(6) In each of the above-described embodiments, the holding and rotating unit 35 holds the substrate W having the back surface facing upward in a horizontal position. Further, the spin base 41 of the holding and rotating unit 35 is disposed below the substrate W. In this regard, the holding and rotating unit 35 may be disposed on the opposite side in the vertical direction. That is, the spin base 41 of the holding and rotating unit 35 is disposed above the substrate W. Further, the holding and rotating unit 35 holds the substrate W having the back surface facing downward in a horizontal position. In this case, the polishing tool 96 is brought into contact with the substrate W having the back surface facing downward from the lower side of the substrate W.

### INDUSTRIAL APPLICABILITY

As described above, the present invention is suitable for a polishing head for polishing a back surface of a substrate, a polishing device including the polishing head, and a substrate processing device.

### REFERENCE SIGNS LIST

1 substrate processing device
W substrate
22 polishing unit
35 holding and rotating unit
37, 37A polishing mechanism
96, 96A, 96B polishing tool
100 shaft
201, 201A, 201B polishing head
203 gas supply pipe
205 suction pipe
207 rotary joint
209 fixed-side body
211 rotating-side body
213 gas supply source
215 flow rate regulating valve
217 on-off valve
219 suction source
221 on-off valve
223, 223A, 223B head body
225, 225A cover
227, 241 first flow path
229, 243 second flow path
235, 251. 255 ejection port
237, 248 suction port

1. A polishing head that polishes a substrate, comprising:
a polishing tool including a resin body in which abrasive grains are dispersed;
an ejection port through which gas is ejected toward dust particles generated as a result of polishing by the polishing tool; and
a suction port through which the dust particles generated as a result of polishing by the polishing tool are sucked.

2. The polishing head according to claim 1, wherein the ejection port is provided along an outer peripheral surface of the polishing tool, and the suction port is provided along the outer peripheral surface of the polishing tool and is provided in a line-symmetrical relation with the ejection port as viewed from above.

3. The polishing head according to claim 1, wherein the polishing tool is provided in an annular shape as viewed from above, the ejection port is provided at a center of the polishing tool, and the suction port is provided all over an outer peripheral surface of the polishing tool.

4. The polishing head according to claim 1, wherein
the polishing tool includes a porous member having holes communicating with each other,
the ejection port is provided on a lower surface of the polishing tool, and
the suction port is provided all over an outer periphery of the polishing tool.

5. The polishing head according to claim 1, wherein
the gas is discontinuously ejected from the ejection port.

6. A polishing device that polishes a substrate, comprising:
a polishing head according to claim 1;
a head drive mechanism that drives the polishing head to rotate about a vertical axis;
a holding and rotating unit that rotates the substrate held in a horizontal position;
a gas supply pipe through which gas is supplied to an ejection port of the polishing head; and
a suction pipe through which suction is performed from a suction port of the polishing head.

7. The polishing device according to claim 6, further comprising:
a control valve that controls a flow of the gas through the gas supply pipe; and
a control unit that operates the control valve,
wherein the control unit operates the control valve to intermittently eject the gas from the polishing head.

8. The polishing device according to claim 7, wherein
the control unit operates the control valve so as to prevent a flow rate of the gas ejected from the ejection port from exceeding a flow rate of the gas sucked through the suction pipe.

9. A substrate processing device comprising a polishing device according to claim 6.
